(19) United States
(12) Patent Application Publication
(10) Pub. No.: US 2012/0262985 A1
(43) Pub. Date: Oct. 18, 2012

(54) MULIT-BIT CELL

(75) Inventors: Ying Qian WANG, Singapore (SG); Yu CHEN, Singapore (SG); Swee Tuck WOO, Singapore (SG); Bangun INDAJANG, Singapore (SG); Sung Mun JUNG, Singapore (SG)

(73) Assignee: GLOBALFOUNDRIES SINGAPORE Pte. Ltd., Singapore (SG)

(21) Appl. No.: 13/085,451

(22) Filed: Apr. 12, 2011

(51) Int. Cl. G11C 11/34; H01L 21/336; H01L 29/792; B82Y 30/00

(52) U.S. Cl. 365/184; 257/325; 438/591; 257/E21.423; 257/E29.309; 977/943

(57) ABSTRACT

A method for forming a device is disclosed. The method includes providing a substrate prepared with a primary gate and forming a charge storage layer on the substrate over the primary gate. A secondary gate electrode layer is formed on the substrate over the charge storage layer. The charge storage and secondary gate electrode layers are patterned to form first and second secondary gates on first and second sides of the primary gate.

### BACKGROUND

Non-volatile memory (NVM) circuits have achieved widespread adoptions for code and data storage applications. For example, non-volatile split gate memory cells embedded with silicon nano-crystals have been investigated.

An important aspect of NVM circuits is their performance, which includes endurance (number of programming or write/erase cycles) and data retention after write/erase cycling. Within the industry, the performance of NVM technology has been characterized extensively. Generally, the NVM circuits should be able to endure over 100 thousand to 1 million programming cycles with data retention exceeding 20 years, even at extreme ambient temperatures. Programming the memory to a program state involves, for example, injecting hot electrons into the gate dielectric of the floating or select gate of the memory cell to increase the threshold voltage. Erasing the memory involves, for example, Fowler-Nordheim (FN) tunneling which tunnels electrons to the control gate to lower the threshold voltage of the memory cell.

### SUMMARY

A method for forming a device is disclosed. The method includes providing a substrate prepared with a primary gate and forming a charge storage layer on the substrate over the primary gate. A secondary gate electrode layer is formed on the substrate over the charge storage layer. The charge storage and secondary gate electrode layers are patterned to form first and second secondary gates on first and second sides of the primary gate.

A device is also presented. The device includes a substrate with a primary gate on the substrate. The device also includes first and second secondary gates on first and second sides of the primary gate. The secondary gates include a charge storage layer and a secondary gate electrode over the charge storage layer.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following

FIG. 1 shows an embodiment of a memory cell;

FIG. 2a shows an embodiment of a memory array;

FIGS. 2b-d show different memory operations of a memory array;

FIG. 3 shows a cross-sectional view of an embodiment of a memory cell;

FIGS. 4a-f show an embodiment of a process for forming a memory cell; and

FIGS. 5a-b show a layout of an embodiment of a memory array or sector.

### DETAILED DESCRIPTION

Embodiments generally relate to semiconductor devices. More particularly, some embodiments relate to memory devices, such as non-volatile memory (NVM) devices. Such memory devices, for example, can be incorporated into standalone memory devices, such as USB or other types of portable storage units, or ICs, such as microcontrollers or system on chips (SoCs). The devices or ICs can be incorporated into or used with, for example, consumer electronic products, or relate to other types of devices.

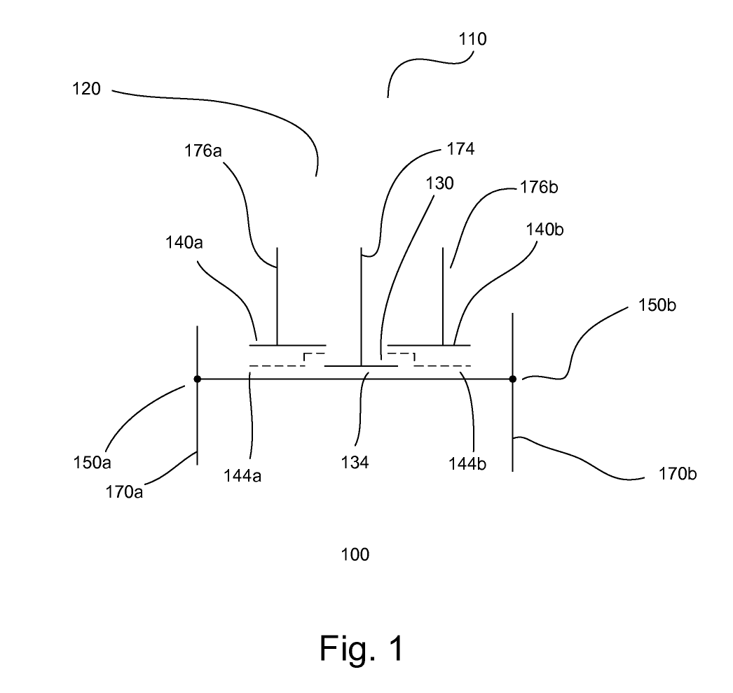

FIG. 1 shows a schematic diagram of an embodiment of a memory cell 100. The memory cell, in one embodiment, may be a multi-bit memory cell. For example, the memory cell is a dual-bit memory cell capable of storing two bits of data. Providing a multi-bit memory cell storing more than two bits of data may also be useful. For example, the multi-bit memory cell stores 2ⁿ bits of data, wherein n≧1. In one embodiment, the memory cell is a multi-bit non-volatile memory cell. Providing other types of multi-bit memory cells may also be useful.

The memory cell includes a transistor 110 with a gate 120. In one embodiment, the gate is a split gate having a primary gate 130 and first and second secondary gates 140a-b. In one embodiment, the secondary gates overlap the primary gate. Providing secondary gates which do not overlap the primary gate may also be useful. The primary gate may serve as a select gate (SG) of the memory cell while the secondary gates serve as control gates (CGs) of the memory cell. In one embodiment, the first and second secondary gates are symmetrical. The first and second secondary gates correspond to first and second bits of the memory cell. For example, a secondary gate corresponds to 2ⁿ⁻¹ bits. In the case where n>1, multiple threshold voltage levels may be employed to provide more than one bit per secondary gate.

A gate dielectric layer 134 separates the primary gate from a substrate. Storage dielectric layers 144a-b separate the secondary gates from the substrate and the primary gate. The storage dielectric layers are capable of storing charge corresponding to the bits of the memory cell. In one embodiment, the storage dielectric layer may be a storage dielectric stack having multiple layers. For example, the storage dielectric layer may be an oxide/nano-crystal/oxide dielectric stack. Other types of dielectric stacks, such as oxide/nitride/oxide or oxide/nitride/Al₂O₃, or storage dielectric layers may also be useful.

The transistor includes first and second source/drain (S/D) regions 150a-b which are provided adjacent to the gate. The S/D regions may be doped regions in the substrate adjacent to the gate. The doped regions include first polarity type dopants for a first polarity type memory cell or device. A doped well may be provided in the substrate in which the memory cell is formed. The doped well is doped with second polarity type dopants. For example, a n-type device includes n-type doped S/D regions and a p-type doped well while a p-type device includes p-type doped S/D regions and a n-type doped well. In one embodiment, the device comprises a n-type device. Alternatively, the device comprises a p-type device.

The gates and S/D regions serve as terminals of the memory cell. For example, S/D regions serve as S/D terminals, the SG serves as the SG terminal and CGs serve as CG terminals. In one embodiment, first and second bitlines (BLs) 170a-b are coupled to the first and second S/D terminals, first and second CG lines (CGLs) 176a-b are coupled to the first and second CGs or secondary gates and a SG line (SGL) 174 is coupled to the SG or primary gate. The SGL, for example, serves as a word line (WL).

Appropriate voltages may be applied to the different terminals via the BLs, CGLs and SGL to perform different memory operations. The different memory operations may include program, read and erase operations. In one embodiment, a program operation comprises injecting hot electrons into the storage gate dielectric layer. This increases the gate threshold voltage. On the other hand, an erase operation tunnels electrons to the control gate. This lowers the gate threshold voltage. When a bit which has been programmed is read, the read current is low due to the higher gate threshold voltage. For a bit which has been erased, the read current is high due to the lower gate threshold voltage. As such, a programmed bit stores a “0” while an erased bit stores a “1”. Providing other configurations of programmed and erased bits may also be useful.

An embodiment of exemplary voltages which are applied to the terminals of the memory cell for different operations are shown in Table 1. In one embodiment, the voltages shown in Table 1 are applied to terminals for different operations of a n-type memory cell formed in a p-type well. Applying other voltages to the terminals for different operations may also be useful.

TABLE 2

| | | 1^{st} Control | 2^{nd} Control | 1^{st} S/D | 2^{nd} S/D | |
|---|---|---|---|---|---|---|
| | Select gate | gate 176a | gate 176b | region | region | well |
| Program 1^{st} bit | 1-1.5 V | 9-9.5 V | 5-6 V | 4.5-5.5 V | 0 V | 0 V |
| Erase 1^{st} bit | 0 V | 13.5-15 V | Float | 0 V | 0 V | 0 V |
| Read 1^{st} bit | 1-1.5 V | 1.6 V | 5-6 V | 0 V | 0.5 V | 0 V |
| Program 2^{nd} bit | 1-1.5 V | 5-6 V | 9-9.5 V | 0 V | 4.5-5.5 V | 0 V |
| Erase 2^{nd} bit | 0 V | Float | 13.5-15 V | 0 V | 0 V | 0 V |
| Read 2^{nd} bit | 1-1.5 V | 5-6 V | 1.6 V | 0.5 V | 0 V | 0 V |

As described, the multi-bit memory cell includes symmetrical first and second secondary gates. Each of the secondary gates includes an underlying charge storage layer, resulting in two charge storage nodes. The multi-bit memory cell also includes a common primary gate for controlling the two secondary gates. By providing a common primary gate, one less primary gate terminal is needed as compared to conventional memory cells which have one primary gate associated with one secondary gate. This advantageously reduces the area size per charge storage node of the memory cell. For example, the cell size can be reduced by at least ⅓ as compared to conventional memory cells. Furthermore, since the two charge storage nodes are physically separated and each node has its own control gate, disturbance between the charge storage nodes is avoided.

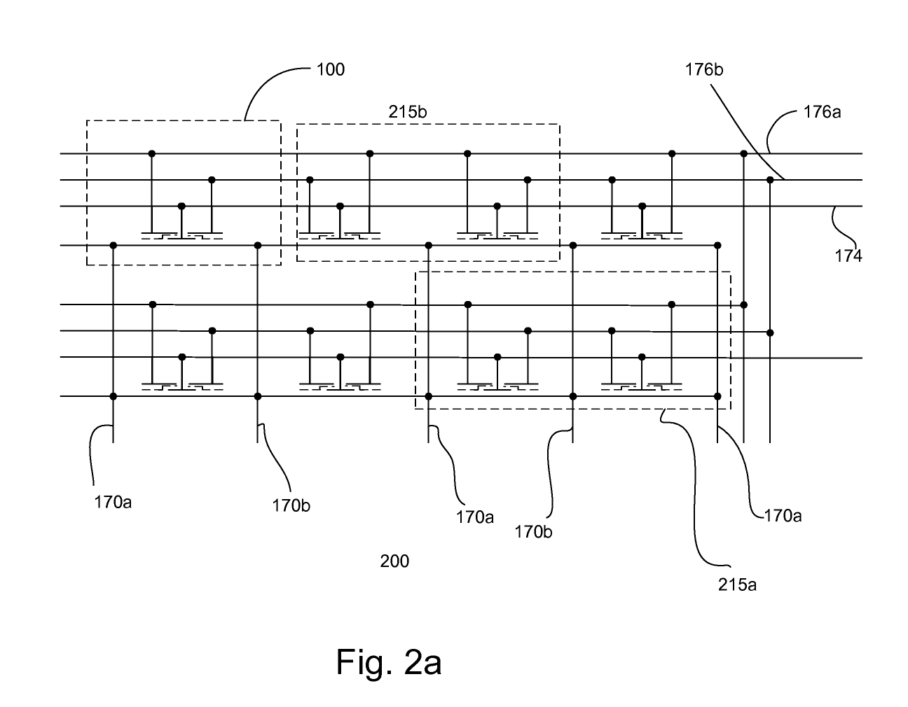

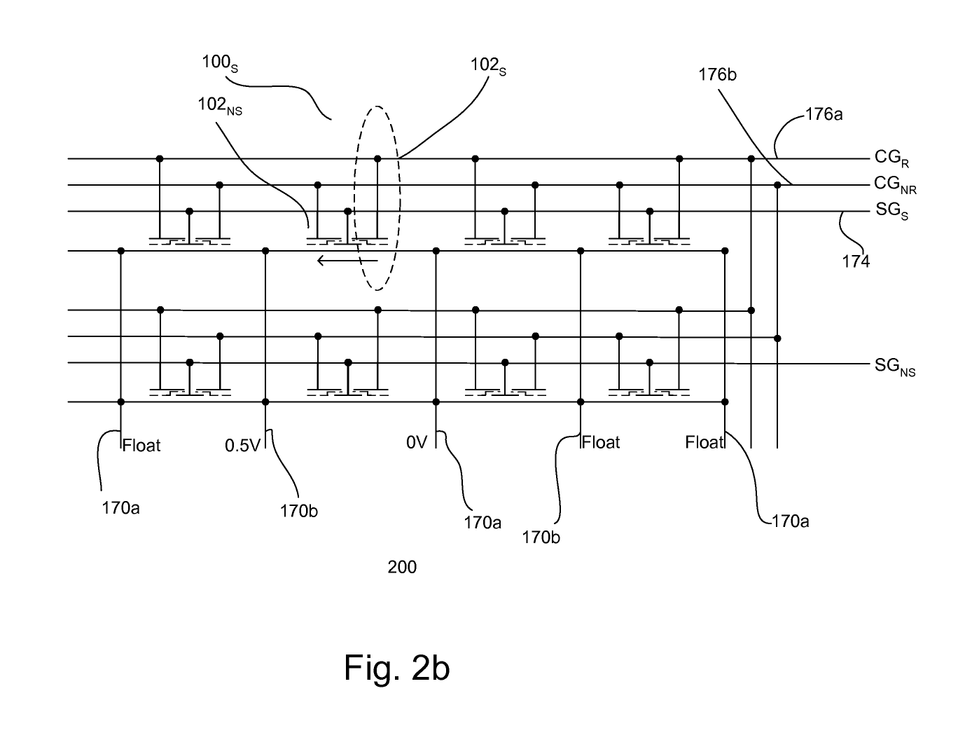

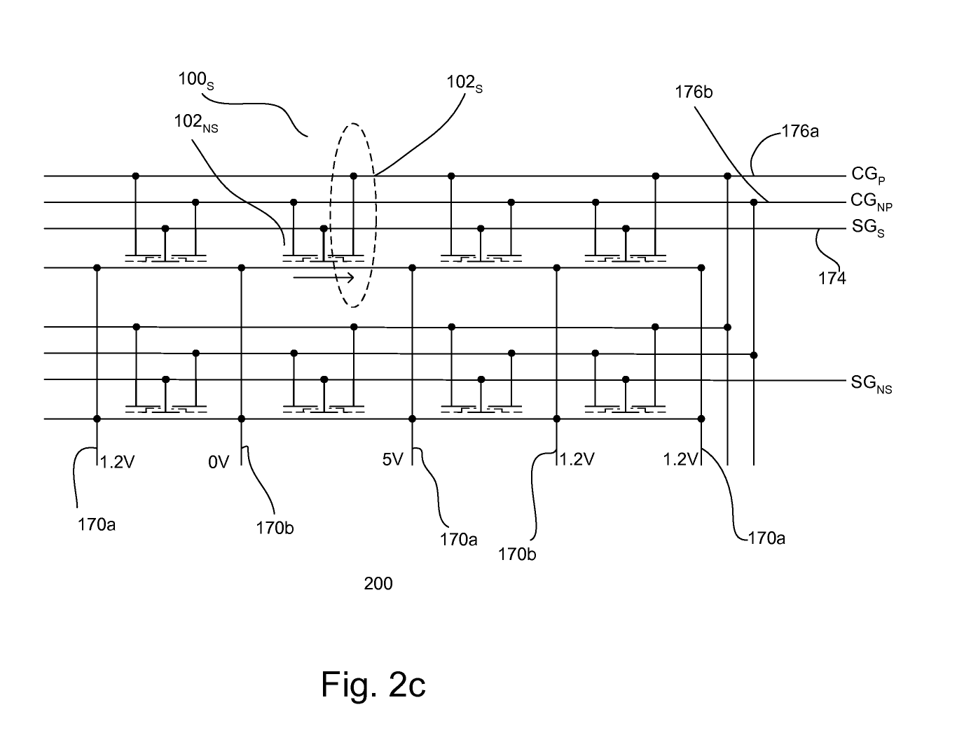

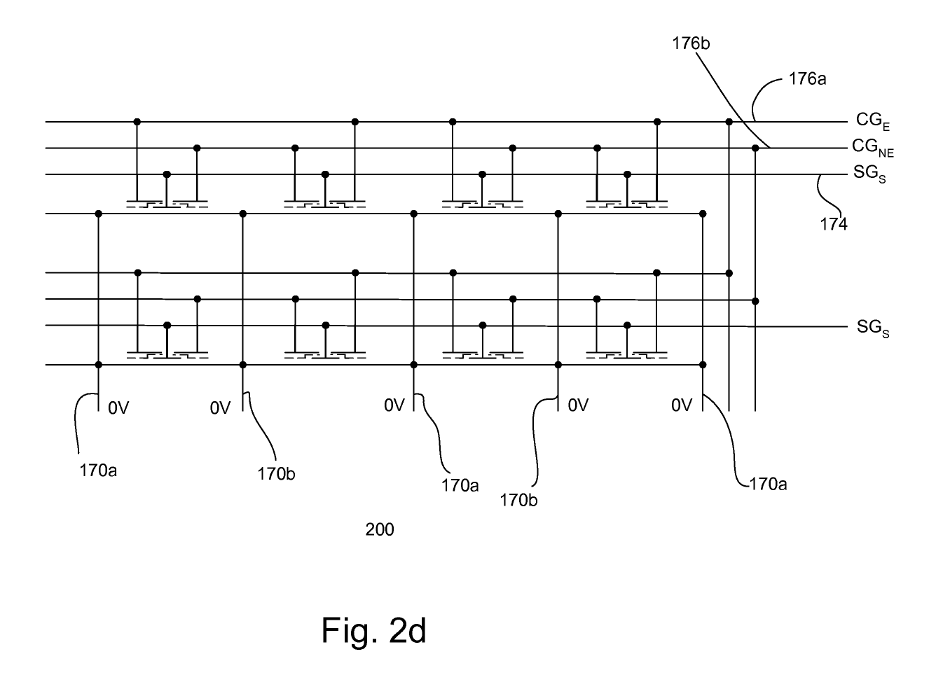

FIG. 2a shows an embodiment of a memory array 200. In one embodiment, the memory array may be a non-volatile memory array. The memory array includes a plurality of memory cells 100 arranged in rows and columns. The memory cells, for example, are multi-bit memory cells 100, as described in FIG. 1. The memory cells are coupled in the column direction by bitlines 170a-b and in the row direction by CGLs 176a-b and SGL 174. It is understood that the directions of the lines are depicted schematically only and that the actual layout of the different lines may be different.

In one embodiment, adjacent memory cells are configured as mirror images of each other. For example, adjacent memory cells of a memory cell pair 215a may have second secondary gates which are adjacent to each other. In such cases, the two adjacent memory cells share a common second BL 170b. Other adjacent memory cells, such as memory cell pair 215b, may have first secondary gates which are adjacent to each other. In such cases, the two adjacent memory cells share a common first BL 170a.

In one embodiment, the memory cells are arranged in sectors which include multiple columns and rows. For example, the memory cells may be arranged in sectors which include 8 rows and 2,000 columns. A row of memory cell includes two CGLs and one SGL. A column of memory cell, for example, includes two BLs. In one embodiment, memory cells of a row may be isolated by isolation regions, such as shallow trench isolations (STIs) while memory cells of a column are not isolated from each other. Providing other row and column configurations may also be useful.

In one embodiment, the memory cells of a sector share common first CGLs and common second CGLs. Sharing of common second CGLs advantageously reduces the number of CG decoders needed, thereby reducing complexity and design area of the device. A SGL controls an individual row of cells in the sector. By applying appropriate voltages to the first and second CGLs, SGLs and BLs, a bit or multiple bits of the memory sector may be selected for accessing. In some embodiments, an erase operation may be applied to a whole sector (sector erase). For example, in a sector erase, a sector of memory cells may be erased simultaneously, in particular, when these cells share the same CGL.

FIG. 2b illustrates a read access of an embodiment of a memory array 200. To select a memory cell to access, the SGL of the row to which the selected cell 100_{S} is coupled is applied with a SG select (SG_{S}) signal. All other SGLs of the memory sector are applied with a SG non-select (SG_{NS}) signal. The access is to one of two bits of the memory cell. To select the desired bit of the selected memory cell to access, a CG read (CG_{R}) is applied to CGL coupled to the selected bit 102_{S} while a CG non-read (CG_{NR}) signal is applied to the CGL coupled to the non-selected bit 102_{NS}. The BLs all have a BL non-select read (BL_{NSR}) signal except for the BLs coupled to the selected memory cell. The BL on the side of the selected bit of the memory cell has a BL select bit read signal (BL_{SBR}) while the BL on the drain side of the non-selected bit has a BL non-select bit read signal (BL_{NSBR}).

In one embodiment, SGₛ signal is equal to about 1V and SG_{NS} signal is equal to about 0V. The CG_{R} signal is equal to about 1.6V and the CG_{NR} signal is equal to about 5V. As for the BL_{NSR} signal, it is a floated signal while BL_{SBR} is equal to about 0V and the BL_{NSBR} signal is equal to about 0.5V. Providing other voltages for the different signals to perform the read access may also be useful.

FIG. 2c illustrates a program access of an embodiment of a memory array 200. To select a memory cell to access, the SGL of the row which the selected cell 100_{S} is coupled is applied with a SG select (SG_{S}) signal. All other SGLs of the memory sector are applied with a SG non-select (SG_{NS}) signal. The access is to one of two bits of the selected memory cell. To select the desired bit of the selected memory cell to access, a CG program (CG_{P}) signal is applied to CGL coupled to the selected bit 102_{S} while a CG non-program (CG_{N}) signal is applied to the CGL coupled to the non-selected bit 102_{NS}. The BLs all have a BL non-program (BL_{NP}) signal except for the BLs coupled to the selected memory cell. The BL on the side of the selected bit has a BL program high (BL_{PH}) signal while the other BL of the selected cell has a BL program low (BL_{PL}) signal.

In one embodiment, SG_{S} signal is equal to about 1V and SG_{NS} signal is equal to about 0V. The CG_{P} signal is equal to about 9V and the CG_{NP} signal is equal to about 5V. As for the BL_{NP} signal, it is equal to about 1.2V, BL_{PH} signal is equal to about 5V and BL_{PL} is equal to about 0V. Providing other voltages for the different signals to perform the program access may also be useful. The arrow indicates the electron injection path.

FIG. 2d illustrates a sector erase operation of an embodiment of a memory array 200. To select a sector of memory cell to access, the SGLs of the sector are applied with a SG_{S} signal. The first and second CGLs of the sector are applied with a CG erase (CG_{E}) signal. For non-selected sectors, the CGLs are applied with a CG non-erase (CG_{NE}) signal. The BLs are all applied with a BL erase (BL_{E}) signal.

In one embodiment, SG_{S} signal is equal to about 1V. The CG_{E} signal is equal to about 14V and the CG_{NE} signal is equal to about 0V. The BL_{E} signal is equal to about 0V. Providing other voltages for the different signals to perform the sector erase may also be useful.

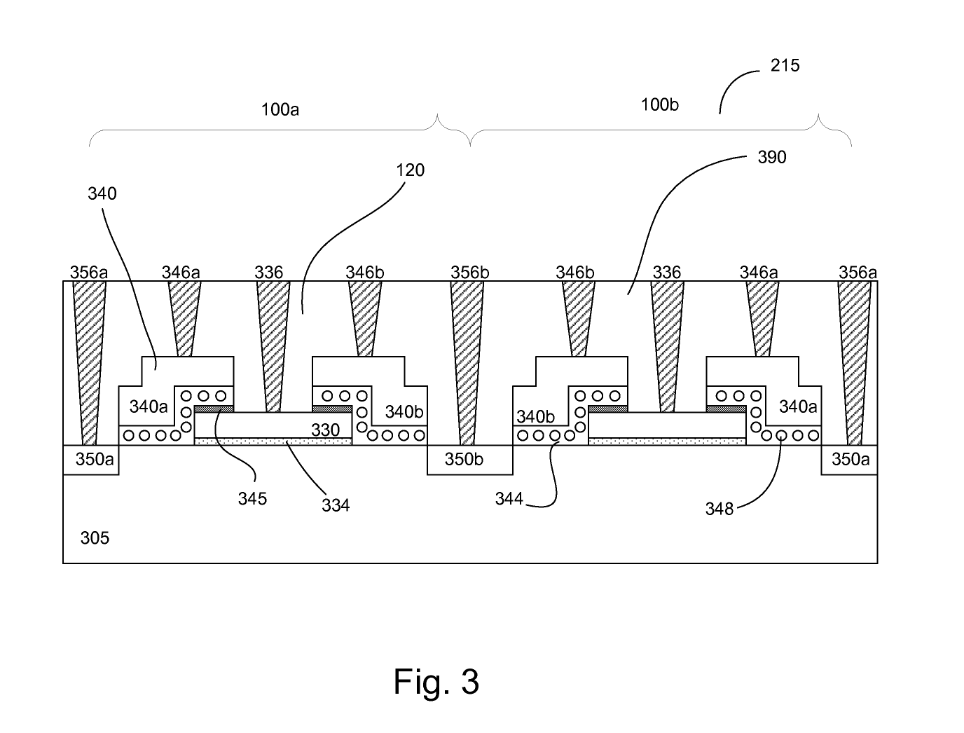

FIG. 3 shows a cross-sectional view of an embodiment of a device. The device includes a substrate 305. The substrate, for example, may be a silicon substrate. The substrate can be lightly doped with p-type dopants. Other types of semiconductor substrates may also be used. For example, the substrate may be silicon germanium or silicon-on-insulator (SOI) as well as intrinsic or doped with other types of dopants or dopant concentrations.

The substrate can be prepared with a memory region containing memory cells of the device. The memory region can be referred to as an array region. Providing a substrate prepared with other types of regions (not shown) may also be useful. For example, the substrate may include a logic region for support or other types of logic circuitry. The substrate may also include regions for other types of circuitry, depending on the type of device or IC. For example, the logic region may include sub-regions for high voltage (HV), intermediate voltage (IV) and low voltage (LV) devices.

In one embodiment, the memory cells are multi-bit memory cells. For example, the memory cells are dual-bit memory cells with first and second bits. The memory cells, in one embodiment, are non-volatile multi-bit memory cells. Providing other types of multi-bit memory cells may also be useful. As shown, the memory cell region includes first and second memory cells 100a-b. The first and second memory cells may be a memory cell pair 215 of the device. For example, the memory cell pair may be adjacent memory cells of a column of memory cells. It is understood that the memory cell region includes numerous memory cells arranged in columns and rows to form a memory array. The array may be configured to have sub-arrays or sectors. Shallow trench isolation (STI) may be used to isolate adjacent cells of a row.

The array region may include a doped well (not shown) with dopants of a second polarity type. The doped well may be intermediately or heavily doped. Providing a doped well having other dopant concentrations may also be useful. The doped well may be a common doped well in the array region for the memory cells. In one embodiment, the array well is biased at an array well bias voltage (V_{bias}.). In one embodiment, V_{bias} is about 0V. The second polarity type doped well serves as a well for a first polarity type device. In one embodiment, the second polarity type comprises p-type. For example, the p-type doped well serves as a well for a n-type memory cell. Providing a n-type doped well may also be useful. P-type dopants can include boron (B), aluminum (Al), indium (In) or a combination thereof while n-type dopants can include phosphorus (P), arsenic (As), antimony (Sb) or a combination thereof.

The substrate includes isolation regions (not shown) to isolate active device regions from other active device regions, as required. The isolation regions, for example, are shallow trench isolation (STI) regions. Other types of isolation regions are also useful. For example, isolation regions may be employed to isolate adjacent memory cells of a row.

In one embodiment, a memory cell includes a transistor with a gate 120 between first and second terminals. The terminals, for example, are first and second S/D terminals of the transistor. In one embodiment, the terminals are S/D diffusion regions 350a-b having first polarity type dopants for forming a first polarity type memory cell. For example, the S/D diffusion regions include n-type dopants for a n-type memory cell. Providing p-type S/D diffusion regions for a p-type memory cell may also be useful.

The gate, in one embodiment, includes a split gate. The split gate has a primary gate 330 and first and second secondary gates 340a-b. The primary gate is common to the first and second secondary gates. For example, the first and second secondary gates are disposed on first and second sides of the primary gate. The secondary gates correspond to first and second bits of the multi-bit memory cell. A channel of the transistor is disposed in the substrate below the gates and S/D regions. The primary gate may serve as a select gate of the memory cell while the secondary gates serve as control gates of the memory cell.

The primary gate includes a primary gate stack having a primary gate electrode 330 over a primary gate dielectric layer 334. The primary gate electrode includes a gate electrode material. For example, the primary gate electrode is formed from polysilicon. In one embodiment, the primary gate electrode is n-type doped. The primary gate electrode doped with other types of dopants may also be useful. Other types of gate electrode materials, such as metals to form metal gates, may also be useful. The thickness of the primary gate electrode may be about 1000 Å. Providing a primary gate electrode having other thicknesses may also be useful. The primary gate electrode, for example, serves as a SG terminal of the memory cell.

The primary gate dielectric layer is formed from, in one embodiment, a gate dielectric material. In one embodiment, the gate dielectric layer is formed from thermal silicon oxide. In other embodiments, the gate dielectric layer may include other types of gate dielectric material, such as high-k materials. In one embodiment, the gate dielectric layer is a low voltage (LV) gate dielectric layer. For example, the LV gate dielectric layer is employed for LV devices. The thickness of the LV gate dielectric layer may be about 20-35 Å. Providing a LV gate dielectric layer of other thicknesses or other types of gate dielectric layers may also be useful.

The secondary gates are disposed adjacent to the first and second sides of the primary gate. The secondary gates are disposed adjacent to and overlap the first and second sides of the primary gate. For example, a portion of the secondary gate is disposed over a top of the primary gate. A secondary gate includes a secondary gate stack having a secondary gate electrode 340 over a charge storage layer 344. The secondary gate electrode is formed from a gate electrode material. For example, the secondary gate electrode is formed from polysilicon. In one embodiment, the secondary gate electrode is doped with first polarity type dopants. For example, the secondary gate electrode is a n-doped secondary gate electrode. In other embodiments, the secondary gate electrode may be doped with other types of dopants. Other types of gate electrode materials, such as metals to form metal gate electrodes, may also be useful. The secondary gate electrode layer may be about 1500 Å thick. Providing secondary gate electrodes of other thicknesses may also be useful. In one embodiment, the primary and secondary gate electrodes may be of the same material. In other embodiments the primary and secondary gate electrodes may be of different gate electrode materials. The secondary gate electrodes, for example, serve as CG terminals of the memory cell.

The secondary gate dielectric layer separates the secondary gate electrode from the substrate and primary gate electrode. In one embodiment, the secondary gate dielectric layer may be a charge storage layer. The secondary gate dielectric layer may be a dielectric charge storage layer. The charge storage layer, in one embodiment, may be a charge storage stack having multiple layers. For example, the charge storage stack may be an oxide/nano-crystal/oxide dielectric stack. In one embodiment, the bottom oxide layer is about 60 Å, the layer with nano-crystals is about 50 Å, and the top oxide layer is about 150 Å. The different layers may also be provided with other thicknesses.

In one embodiment, the nano-crystals 348 may be silicon or germanium nano-crystals. Other types of nano-crystals, for example, metallic or dielectric nano-crystals may be employed. The nano-crystals can improve charge retention. Other types of charge storage stacks, such as oxide/nitride/oxide or oxide/nitride/Al₂O₃, or storage dielectric layers may also be useful. Providing other types of materials for the charge storage layer may also be useful.

A buffer layer 345 may be provided on the top of the primary gate to separate it from the charge storage layer. The buffer layer, for example, may be an anti-reflective coating (ARC) material. The ARC, for example, comprises Si₃N₄. The buffer layer can serve as an etch stop layer for patterning the secondary gate stack. The buffer layer may be about 100 Å thick. Providing a buffer layer having other thicknesses may also be useful.

A dielectric layer 390 is provided over the substrate, covering the memory cells. The dielectric layer, for example, serves as an interlevel dielectric (ILD) layer. The dielectric layer, for example, may be TEOS. Other types of dielectric materials, such as low-k dielectric materials or high density plasma oxides may also be used.

Contacts are provided in the dielectric layer, coupling to the different terminals of the memory cell. For example, S/D contacts 356a-b are coupled to S/D terminals of the memory cell, CG contacts 346a-b are coupled to the CG terminals, and SG contacts 336 are coupled to the SG terminals. BLs are coupled to the S/D contacts, CGLs are coupled to the CG contacts and SGLs are coupled to the SG contacts.

In one embodiment, the adjacent memory cells are configured as mirror images of each other. For example, adjacent memory cells 110a-b share a common S/D terminal. As shown, the adjacent memory cells share a common second S/D terminal 350b. The second bits of the memory cells are adjacent to each other. In one embodiment, adjacent memory cells of a row are configured as mirror images. For example, some adjacent memory cells share a common first S/D terminal while other adjacent memory cells share a common second S/D terminal. Arranging the memory cells in other configurations may also be useful.

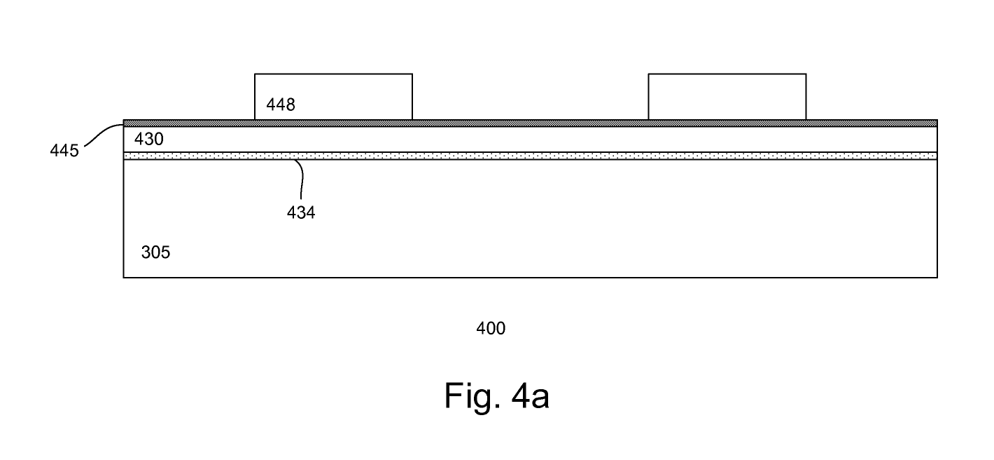

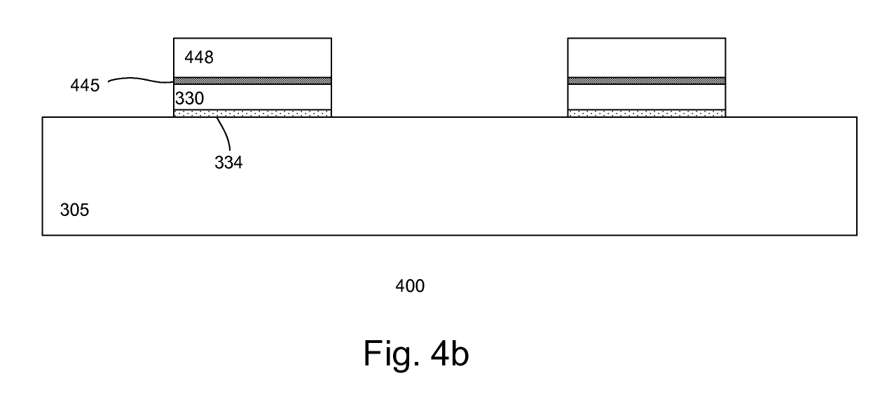

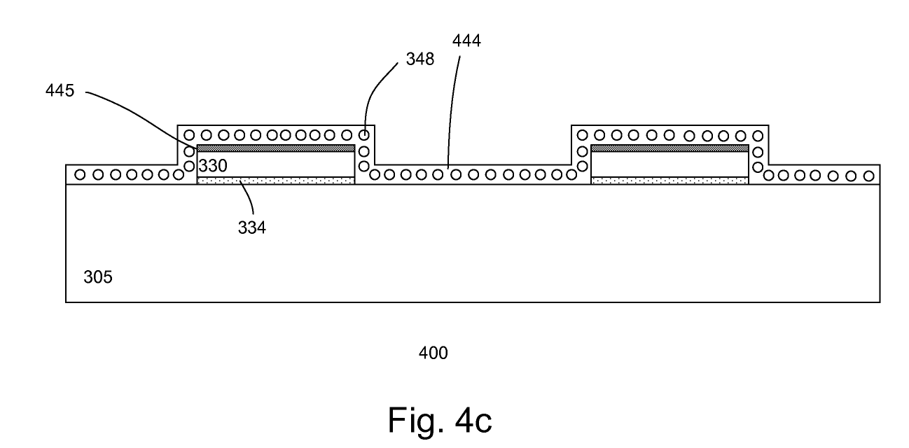

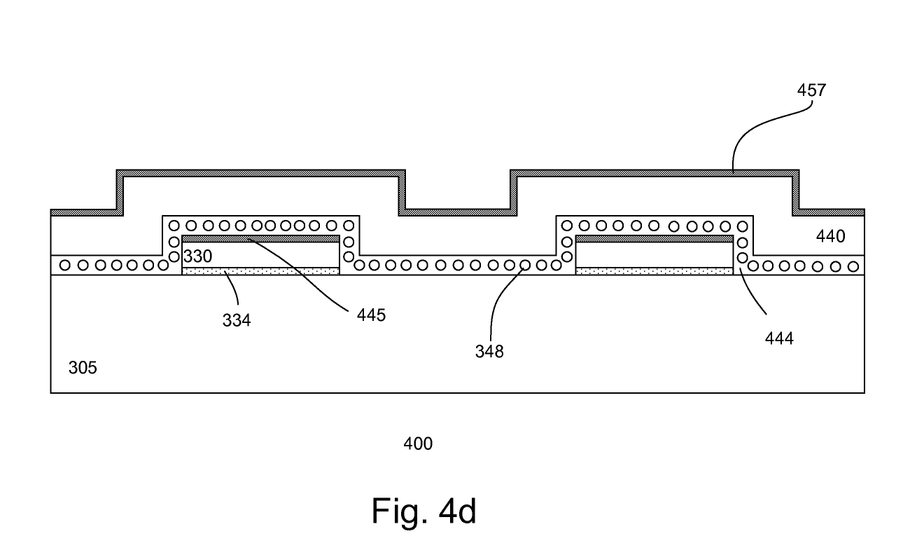

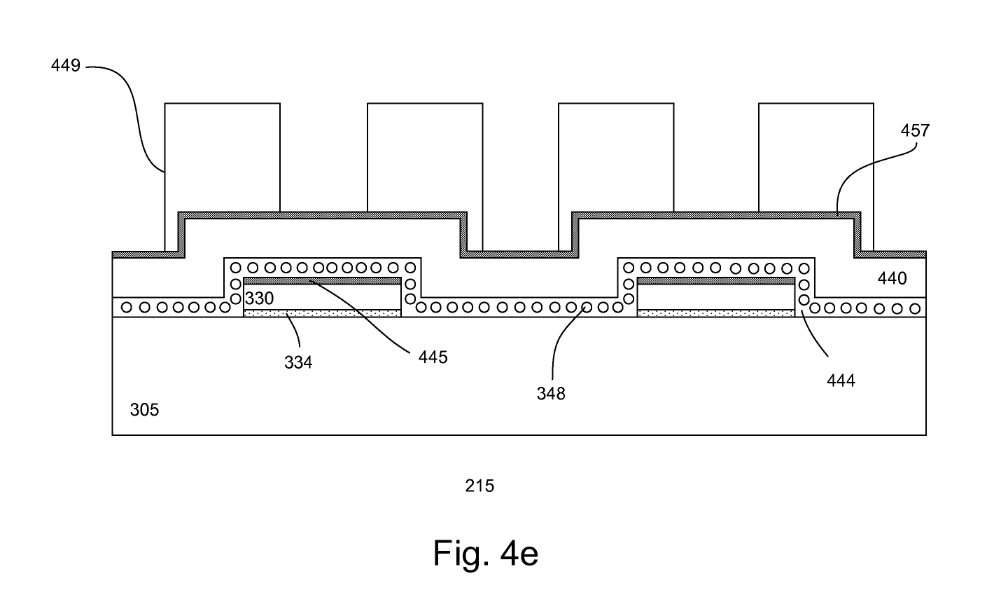

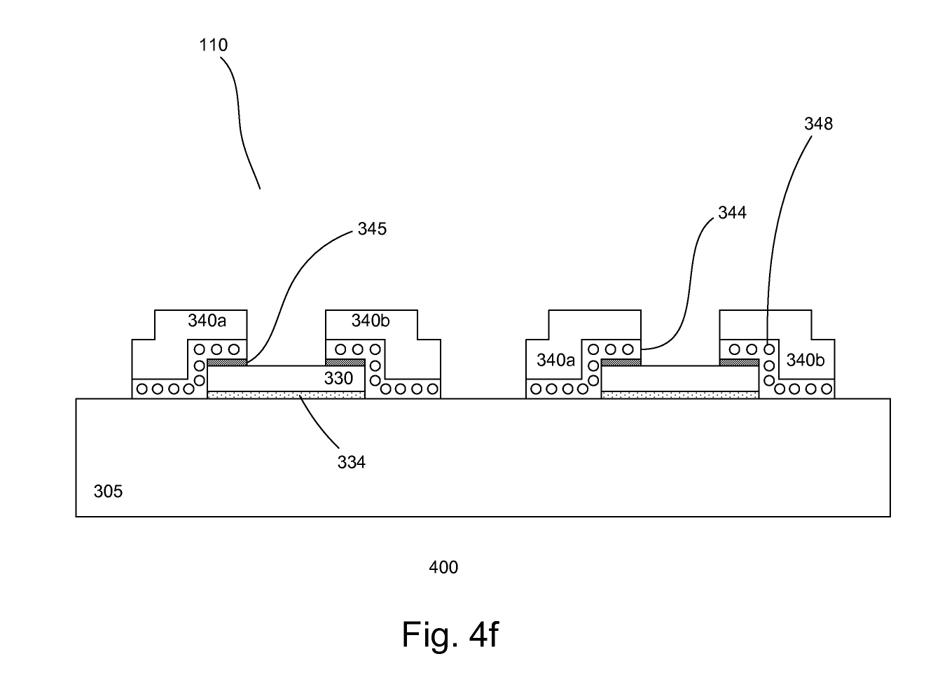

FIGS. 4a-f show cross-sectional views of an embodiment of a process for forming a device or IC 400. Referring to FIG. 4a, a substrate 305 is provided. The substrate can be a silicon substrate. For example, the substrate can be a lightly silicon substrate lightly doped with p-type dopants. Other types of semiconductor substrates, such as silicon germanium or silicon-on-insulator (SOI) as well as intrinsic or doped with other types of dopants or dopant concentrations, are also useful.

The substrate, in one embodiment, is prepared with a memory region for memory cells of the device. The memory region can be referred to as an array region. Providing a substrate prepared with other types of regions (not shown) may also be useful. For example, the substrate may include a logic region for support circuitry. The substrate may also include regions for other types of circuitry, depending on the type of device or IC. For example, the logic region may include sub-regions for HV, IV and LV devices.

Memory cells which are formed in the array region may include multi-bit memory cells. For example, the memory cells may be dual-bit memory cells with first and second bits. The memory cells, in one embodiment, are non-volatile multi-bit memory cells.

The array region may include a doped well (not shown) with dopants of a second polarity type. The doped wells may be intermediately or heavily doped. The doped well may be a common doped well in the array region for the memory cells. The second polarity type can be n-type or p-type, depending on the memory cell type. The second polarity type well is used for first polarity type memory cells. For example, a p-type well is used for n-type memory cells while a n-type well is used for p-type memory cells. P-type dopants can include boron (B), aluminum (Al), indium (In) or a combination thereof while n-type dopants can include phosphorus (P), arsenic (As), antimony (Sb) or a combination thereof

Generally, the IC includes regions with both first and second type wells. To form the doped wells for different regions, ion implantation techniques, such as implantation with a mask, can be used. The first and second type wells can be formed in separate processes. Other techniques for forming the doped wells may also be useful.

The substrate can be prepared with isolation regions (not shown), for example, to separate the different active regions from each other and other active device regions. The isolation regions may be used to separate adjacent memory cells of a row. In one embodiment, the isolation regions are STIs. Various processes can be employed to form the STI regions. For example, the substrate can be etched using etch and mask techniques to form trenches which are then filled with dielectric materials such as silicon oxide. Chemical mechanical polishing (CMP) can be performed to remove excess oxide and provide a planar substrate top surface. The STI regions can be formed, for example, prior to or after the formation of the doped wells. Other processes or materials can also be used to form the STIs.

The substrate may be implanted with dopants to define the initial gate threshold voltage (V_{T}). For example, multiple threshold adjust implants may be performed for different types of devices.

As shown, the substrate is prepared with various layers of primary gate stacks of the memory cells. In one embodiment, a primary gate dielectric layer 434 is formed on the substrate. The primary gate dielectric layer, in one embodiment, is a LV gate dielectric layer. In one embodiment, the primary gate dielectric layer may be a silicon oxide layer. In one embodiment, the gate dielectric layer may be formed by thermal oxidation. The thermal oxidation may either be dry or wet oxidation at a temperature of about 800° C. The thickness of the primary gate dielectric layer may be about 20-35 Å. Other thicknesses may also be useful.

In some embodiments, the gate dielectric layer may include other types of materials, for example, such as silicon oxynitride or high-k materials. The gate dielectric layer may be formed using various techniques, such as thermal oxidation or chemical vapor deposition (CVD).

A primary gate electrode layer 430 is deposited on the primary gate dielectric layer. The primary gate electrode layer, in one embodiment, may be polysilicon. The gate electrode layer can be formed as an amorphous or non-amorphous layer. In one embodiment, the gate electrode is doped, for example, with first polarity type dopants. Various techniques may be employed to dope the gate electrode, for example, in-situ doping or ion implantation. Providing an undoped gate electrode layer may also be useful. Other types of gate electrode materials are also useful. The thickness of the primary gate electrode layer may be about 800-1500 Å. Other thicknesses are also useful. To form the primary gate electrode layer, techniques, such as CVD, can be used. Other techniques are also useful.

In one embodiment, an ARC layer 445 is formed on the primary gate electrode layer. The ARC layer is employed to improve lithographic resolution for patterning of the gate layers. In one embodiment, the ARC layer may comprise Si₃N₄ formed by CVD. The thickness of the ARC layer may be about 100 Å. A mask layer 448 is formed over the ARC layer. The mask layer, for example, is formed from photoresist. The mask layer 448 may be formed on the ARC layer by spin-on techniques. Other types of techniques may also be used to form the mask layer.

The mask layer is patterned to selectively remove unwanted portions to form the mask. For example, the mask may be selectively exposed to radiation and developed to remove unwanted portions. In the case of a positive photoresist mask layer, exposed portions are removed. On the other hand, unexposed portions are removed in the case of a negative photoresist mask layer. The remaining portions of the mask layer correspond to the primary gate stacks of the memory cells.

Referring to FIG. 4b, exposed portions of the gate layers unprotected by the patterned mask layer are patterned or removed to form primary gate stacks. An anisotropic etch, such as a reactive ion etch (RIE), may be employed to pattern the gate layers to form the primary gate stacks. After forming the primary gate stacks, the mask layer is removed. For example, the mask layer may be removed by ashing. Other techniques for removing the mask layer may also be useful. This forms primary gate stacks, which include a primary gate dielectric layer, primary gate electrode layer and an ARC layer, on the substrate.

In FIG. 4c, a charge storage layer 444 is formed on the substrate. For example, the charge storage layer covers the primary gate stacks and substrate. In one embodiment, the charge storage layer may be a charge storage stack with nano-crystals 348. For example, the charge storage stack may be an oxide/nano-crystals/oxide stack. The nano-crystals, for example, are silicon nano-crystals. Providing other types of nano-crystals, such as germanium nano-crystals, metal nano-crystals and dielectric nano-crystals, may also be useful. In some embodiments, other types of charge storage layers or layered stacks may also be employed. For example, the charge storage stack may be oxide/nitride/oxide or oxide/nitride/Al₂O₃. Various techniques may be employed to form the charge storage layer, including thermal oxidation, CVD, thermal treatment or a combination thereof.

In one embodiment, the charge storage layer is an oxide/nano-crystals/oxide stack. To form the charge storage stack, a first sub-layer of the charge storage stack is formed on the substrate. In one embodiment, the first sub-layer serves as a tunneling layer. The first sub-layer is a silicon oxide layer. The first sub-layer is formed by, for example, thermal oxidation. The thermal oxidation may be wet or dry oxidation at a temperature of about 800° C. The first sub-layer may have a thickness of about 40-80 Å. Other thicknesses for the first sub-layer may also be useful.

A second sub-layer is formed over the first sub-layer. The second sub-layer, for example, serves as a charge storage layer. The second sub-layer is subsequently processed to form nano-crystals. In one embodiment, the second sub-layer may be silicon to form silicon nano-crystals. The second sub-layer, for example, may be amorphous silicon. Other types of silicon containing layers may also be useful. Providing other types of second sub-layers for different types of nano-crystals, for example, germanium is also useful. The thickness of the second sub-layer is, for example, about 50 Å.

The processing of the sub-layers consumes the second sub-layer to form nano-crystals. In one embodiment, the processing includes an anneal to form the nano-crystals. In one embodiment, the second sub-layer comprises an amorphous silicon layer which is deposited over the first sub-layer by chemical vapor deposition. The amorphous silicon layer may be about 50 Å. The second sub-layer is then subjected to in-situ anneal in N₂ ambience at about 700° C. In another embodiment, the nano-crystals are formed by implanting silicon into the first sub-layer comprising silicon oxide followed by anneal. A third sub-layer is formed over the second processed sub-layer with nano-crystals. The third sub-layer, for example, serves as a cap layer over the nano-crystals. The cap layer can be formed by, for example, CVD or rapid thermal CVD (RTCVD). The thickness of the cap layer may be, for example, 100-150 Å. The cap layer improves tunneling voltage.

A secondary gate electrode layer 440 is deposited on the substrate, as shown in FIG. 4d. The secondary gate electrode layer, in one embodiment, may be polysilicon. The gate electrode layer can be formed as an amorphous or non-amorphous layer. In one embodiment, the gate electrode layer comprises a doped gate electrode layer. For example, the gate electrode layer may be doped with first polarity type dopants. For example, the gate electrode layer is doped with n-type dopants. Other types of gate electrode materials are also useful. The thickness of the second gate electrode layer is, for example, about 800-1500 Å. Other thicknesses are also useful. To form the secondary gate electrode layer, techniques, such as chemical vapor deposition (CVD), can be used. Other techniques are also useful.

In one embodiment, an ARC layer 457 is formed on the secondary gate electrode layer. The ARC layer is employed to improve lithographic resolution for patterning of the gate layers. In one embodiment, the ARC layer comprises Si₃N₄ formed by CVD. The thickness of the ARC layer may be, for example, 100 Å.

Referring to FIG. 4e, a mask layer 449 is formed over the ARC layer. The mask layer, for example, may be photoresist. The mask layer may be formed on the ARC layer by spin-on techniques. Other techniques may also be used to form the mask layer. The mask layer is patterned to correspond to the secondary gates. For example, the mask layer protects the gate layers which correspond to the secondary gates of the memory cells while exposing other portions of the gate layers.

As shown in FIG. 4f, the gate layers are patterned to form secondary gates 340a-b adjacent to first and second sides of the primary gate. In one embodiment, the secondary gates overlap the primary gate. For example, a portion of the secondary gates is disposed over the top of the primary gate. An anisotropic etch, such as a reactive ion etch (RIE), may be employed to pattern the gate layers to form the secondary gate stacks. The etch, for example, may be selective to silicon, removing exposed portions of the secondary gate layer and charge storage layer. The etch, for example, may use the ARC layer 445 as an etch stop layer, leaving the primary gate stack in place. After forming the secondary gate stacks, the etch may continue to remove the ARC layer 445 until a portion of the top of the primary gate is exposed. The remaining portion of the ARC layer 345 may serve as a buffer layer, separating the primary gate from the charge storage layer.

After forming the secondary gate stacks, the mask layer is removed. For example, the mask layer may be removed by ashing. Other techniques for removing the mask layer may also be useful.

The process continues to form the device, for example, as shown in FIG. 3. Additional processing can include forming gate sidewall spacers, S/D diffusion regions and salicide contacts, ILD layer, contacts to terminals, and one or more interconnect levels, as well as final passivation, dicing, assembly and packaging. Other processes are also useful. For example, other components, such as LV, IV, HV and I/O devices can be formed prior to forming the interconnections. The memory cells can be formed as a memory device or embedded into a part of ICs.

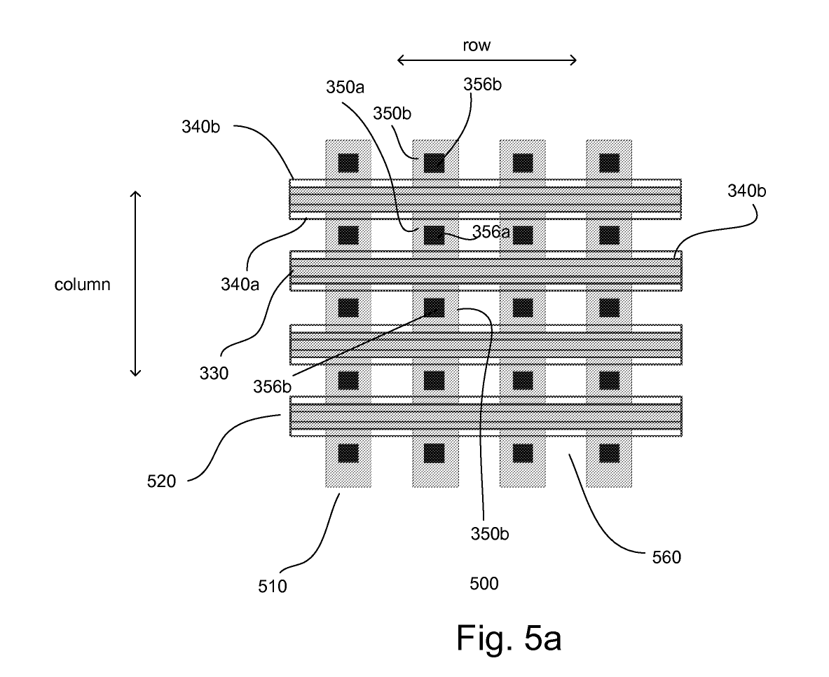

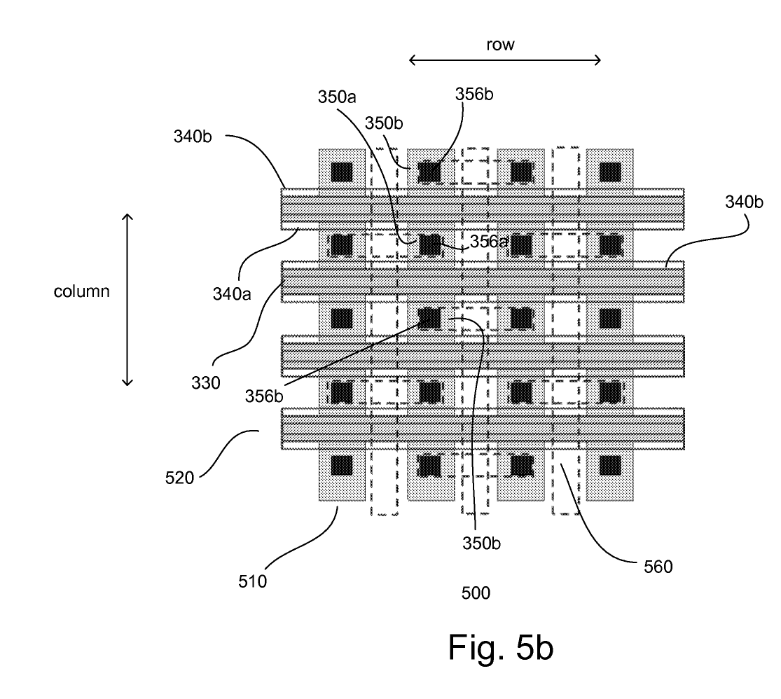

FIGS. 5a-b show a layout of an embodiment of a memory array or sector 500. Referring to FIG. 5a, the layout is prior to metallization or metal 1 (M1). The layout includes elongated active regions 510 disposed in a substrate. The active regions are disposed in the substrate in a first direction. The first direction, for example, corresponds to the column direction of the array. The active regions are separated by inactive regions 560. The inactive regions, for example, are STIs which isolate the active regions from each other.

A plurality of gate electrodes 520 is disposed on the substrate over the active regions in a second direction. As shown, the first and second directions, for example, are perpendicular. Providing non-perpendicular first and second directions may also be useful. The second direction corresponds to the row direction of the memory sector. A gate electrode includes a primary gate electrode 330 and first and second secondary gate electrodes 340a-b. Adjacent to the gate electrode in the substrate are S/D diffusion regions 350a-b. Contacts 356a-b are provided to the S/D diffusion regions. Contacts (not shown) are also provided to the primary gate electrodes.

FIG. 5b shows the layout after M1. The metal layer M1 is patterned to form bitlines 560 of the memory sector. As shown, a pair of adjacent memory cells shares a common bitline. Other configurations of the memory sector may also be useful.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A method for forming a device comprising:
providing a substrate prepared with a primary gate;
forming a charge storage layer on the substrate over the primary gate;
forming a secondary gate electrode layer on the substrate over the charge storage layer; and
patterning the charge storage and secondary gate electrode layers to form first and second secondary gates on first and second sides of the primary gate.

2. The method of claim 1 wherein the charge storage layer comprises a dielectric charge storage layer.

3. The method of claim 2 wherein the charge storage layer comprises nano-crystals.

4. The method of claim 1 wherein the primary gate comprises a primary gate electrode over a primary gate dielectric layer.

5. The method of claim 1 wherein the first and second secondary gates are disposed adjacent to and overlap the first and second sides of the primary gate.

6. The method of claim 1 wherein the device comprises a memory cell.

7. The method of claim 6 wherein the primary gate comprises a select gate of the memory cell.

8. The method of claim 6 wherein the secondary gates comprise control gates of the memory cell.

9. A device comprises:
a substrate with a primary gate on the substrate; and
first and second secondary gates on first and second sides of the primary gate, wherein the secondary gates comprise a charge storage layer and a secondary gate electrode over the charge storage layer.

10. The device of claim 9 wherein the charge storage layer comprises a dielectric charge storage layer.

11. The device of claim 10 wherein the charge storage layer comprises nano-crystals.

12. The device of claim 9 wherein the primary gate comprises a primary gate electrode over a primary gate dielectric layer.

13. The device of claim 9 wherein the first and second secondary gates are disposed adjacent to and overlap the first and second sides of the primary gate.

14. The device of claim 9 wherein the device comprises a memory cell.

15. The device of claim 14 wherein the primary gate comprises a select gate of the memory cell.

16. The device of claim 14 wherein the secondary gates comprise control gates of the memory cell.

17. A memory cell with two physical charge storage nodes represented by two secondary gate stacks comprising:
a primary gate, with a gate dielectric underneath;
first and second secondary gates adjacent to first and second sides of the primary gate;
charge storage layers separating the primary and secondary gates; and
first and second charge storage nodes formed by the secondary gates and charge storage layers.

18. A method of operating a memory cell with a primary gate and first and second secondary charge storage nodes comprising:
programming the first secondary charge storage node comprises applying a first set of programming voltages;
programming the second secondary charge storage node comprises applying a second set of programming voltages;
erasing the first secondary charge storage node comprises applying a first set of erase voltages;
erasing the second secondary charge storage node comprises applying a second set of erase voltages;
reading a first state of the first secondary charge storage node comprises applying a first set of read voltages; and
reading a second state of the second secondary charge storage node comprises applying a second set of read voltages.

19. The method of claim 18 wherein one of the first or second secondary charge storage nodes is accessed at one time.

20. The device of claim 14 wherein the first and second secondary gates correspond to first and second bits of the memory cell.

21. The device of claim 16 wherein the first and second secondary gates correspond to first and second bits of the memory cell.
